(19) United States
(12) Patent Application Publication
(10) Pub. No.: US 2026/0293047 A1
(43) Pub. Date: Sep. 24, 2026

(54) WATER COOLING HEAD

(71) Applicant: COOLER MASTER CO., LTD., Taipei City (TW)

(72) Inventors: Chiu-Yu YEH, Taipei City (TW); Chien-Liang LIN, Taipei City (TW)

(73) Assignee: COOLER MASTER CO., LTD., Taipei City (TW)

(21) Appl. No.: 19/573,060

(22) Filed: Mar. 20, 2026

(30) Foreign Application Priority Data
Mar. 21, 2025 (TW) 114202840

(51) Int. Cl. H05K 7/20

(52) U.S. Cl. CPC H05K 7/20272; H05K 7/20263

(57) ABSTRACT

Aspects of the present disclosure provide a water-cooling head. The water-cooling head includes a housing having a liquid inlet, a heat exchange chamber, an impeller chamber, and a liquid outlet sequentially connected with each other, an impeller disposed in the impeller chamber, and a motor including a circuit board, a stator assembly, and a rotor, wherein the circuit board is disposed on the housing, the stator assembly is disposed on the circuit board, and the rotor is disposed on the impeller.

### RELATED APPLICATIONS

This US application claims priority to Taiwan Application No. 114202840, filed on Mar. 21, 2025, which is incorporated herein by reference in its entirety.

### TECHNICAL FIELD

The present disclosure relates to cooling devices for electronic components, and more particularly to a water cooling head for dissipating heat from electronic heat sources.

### BACKGROUND

Electronic devices such as central processing units and graphics processing units generate a significant amount of heat during operation. In many systems, a water cooling structure is used to dissipate the generated heat.

In a typical configuration, a heat source is thermally coupled to a water cooling head. A cooling liquid flows through the water cooling head and exchanges heat with the heat source, thereby carrying the heat away.

However, as the performance of electronic components enhances, the amount of generated heat also increases. Conventional water cooling structures may not be good enough for heat exchange efficiency to meet the cooling requirements of high-performance electronic components. Accordingly, improvements in the structure of water cooling heads need to be addressed for enhancing cooling performance.

### SUMMARY

Aspects of the present disclosure provide a water-cooling head. The water-cooling head includes a housing having a liquid inlet, a heat exchange chamber, an impeller chamber, and a liquid outlet sequentially connected with each other, an impeller disposed in the impeller chamber, and a motor including a circuit board, a stator assembly, and a rotor, wherein the circuit board is disposed on the housing, the stator assembly is disposed on the circuit board, and the rotor is disposed on the impeller.

In an embodiment, the housing comprises a base, a heat conducting member, a cover, and a flow guide assembly, the liquid inlet and the liquid outlet are located on the base, the heat conducting member and the cover are respectively assembled on opposite sides of the base, the heat conducting member and the base together form the heat exchange chamber, the circuit board is disposed on the cover, the flow guide assembly is disposed in the base, the flow guide assembly and the cover together form the impeller chamber, the flow guide assembly has a first communication passage and a second communication passage, the first communication passage communicates the liquid inlet and the heat exchange chamber, and the second communication passage communicates the heat exchange chamber and the impeller chamber.

In an embodiment, the flow guide assembly comprises a first water guide plate, a second water guide plate, and a third water guide plate sequentially stacked, the first water guide plate is closer to the impeller chamber than the second water guide plate and the third water guide plate, the first water guide plate has a first opening and a second opening, the second water guide plate has a third opening and at least one fourth opening, the third water guide plate has at least one fifth opening, the first opening and the third opening together form the first communication passage, and the second opening, the at least one fourth opening, and the at least one fifth opening together form the second communication passage.

In an embodiment, the first opening is located at a corner of the first water guide plate, the second opening is disposed at a center of the first water guide plate, the third opening is disposed at a corner of the second water guide plate, the at least one fourth opening is disposed on a side of the second water guide plate, the second water guide plate further has a groove, the groove connects the at least one fourth opening, the at least one fifth opening is disposed on a side of the third water guide plate, the first opening and the third opening are aligned with each other, the second opening is aligned with the groove, the at least one fourth opening is aligned with the at least one fifth opening, and the second opening, the groove, the at least one fourth opening, and the at least one fifth opening together form the second communication passage.

In an embodiment, the number of the at least one fourth opening is two, the two fourth openings are respectively disposed on opposite sides of the second water guide plate, the number of the at least one fifth opening is two, the two fifth openings are respectively disposed on opposite sides of the third water guide plate, and the two fourth openings are respectively aligned with the two fifth openings.

In an embodiment, the base includes a chamber inlet and at least one chamber outlet, the at least one chamber outlet is disposed on a side of the chamber inlet, the first communication passage communicates with the heat exchange chamber through the chamber inlet, and the second communication passage communicates with the heat exchange chamber through the at least one chamber outlet.

In an embodiment, the water-cooling head further includes a baffle plate disposed between the base and the heat conducting member, wherein the baffle plate has a slit, and the chamber inlet communicates with the heat exchange chamber through the slit.

In an embodiment, the water-cooling head further includes two sealing members, wherein one of the two sealing members is disposed between the heat conducting member and the base, and the other of the two sealing members is disposed between the cover and the base.

In an embodiment, the impeller comprises a disk portion and a plurality of blades, the disk portion comprises a central portion and a peripheral portion surrounding the central portion, a maximum thickness of the central portion is greater than a thickness of the peripheral portion, and the blades are disposed on the peripheral portion.

In an embodiment, the stator assembly and the rotor are arranged along a rotation axis of the impeller.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a perspective view of a water cooling head according to aspects of the present disclosure.

FIG. 2 illustrates an exploded view of the water cooling head of FIG. 1.

FIG. 3 illustrates another exploded view of the water cooling head of FIG. 1.

FIG. 4 illustrates a bottom view of the water cooling head of FIG. 1.

FIG. 5 illustrates a cross-sectional view taken along line 5-5 of FIG. 4.

FIG. 6 illustrates a cross-sectional view taken along line 6-6 of FIG. 4.

FIG. 7 illustrates a cross-sectional view taken along line 7-7 of FIG. 4.

FIG. 8 illustrates a cross-sectional view taken along line 8-8 of FIG. 4.

FIG. 9 illustrates a perspective view of an impeller used in the water cooling head.

FIG. 10 illustrates a perspective view of a water cooling head according to aspects of the present disclosure.

FIG. 11 illustrates an exploded view of the water cooling head of FIG. 10.

FIG. 12 illustrates another exploded view of the water cooling head of FIG. 10.

### DETAILED DESCRIPTION

Detailed descriptions and technical contents of the present invention are illustrated below in conjunction with the accompanying drawings. However, it is to be understood that the descriptions and the accompanying drawings disclosed herein are merely illustrative and exemplary and not intended to limit the scope of the present invention.

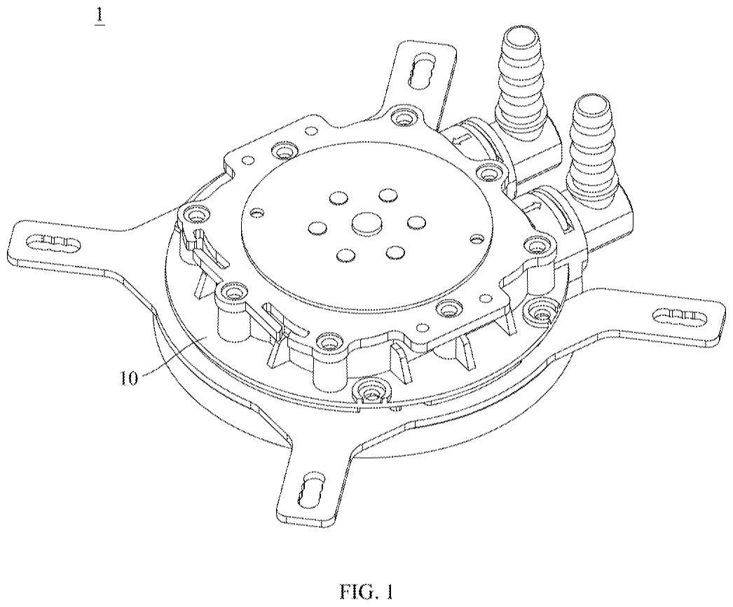

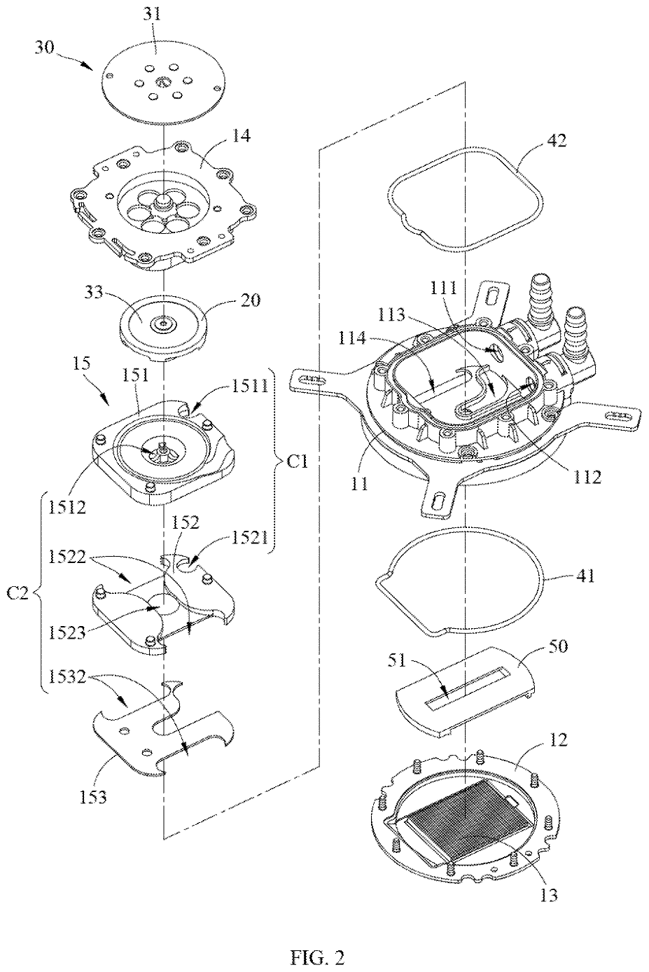

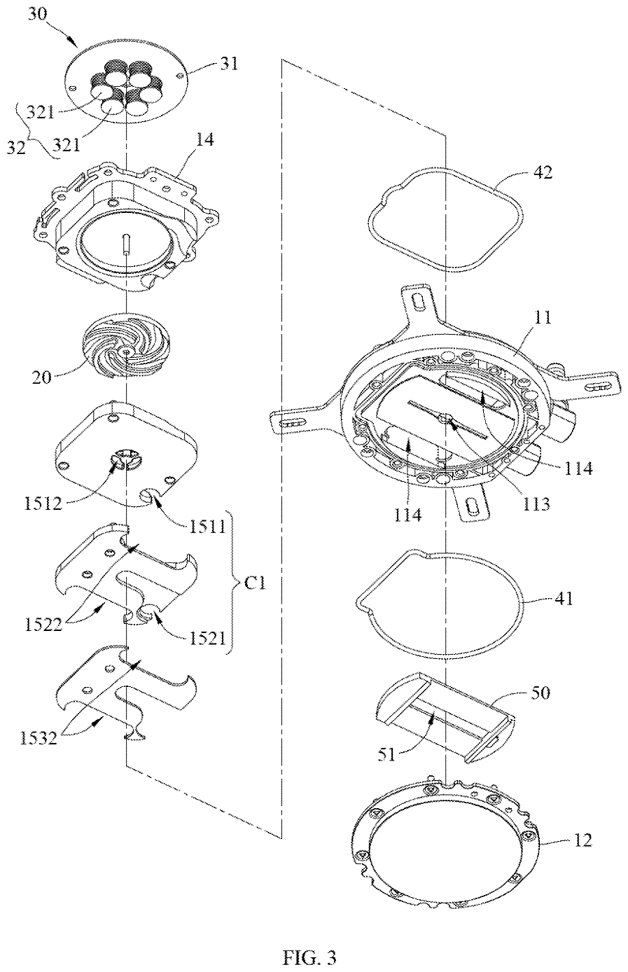

Please refer to FIGS. 1 to 3. FIG. 1 is a perspective view of a water-cooling head according to a first embodiment of the present disclosure. FIG. 2 is an exploded view of the water-cooling head of FIG. 1. FIG. 3 is an exploded view of the water-cooling head of FIG. 1 from another viewing angle.

In this embodiment, the water-cooling head 1 includes a housing 10, an impeller 20, and a motor 30. Additionally, the water-cooling head 1 may further include two sealing members 41, 42. The housing 10 includes a base 11, a heat conducting member 12, a plurality of fin structures 13, a cover 14, and a flow guide assembly 15.

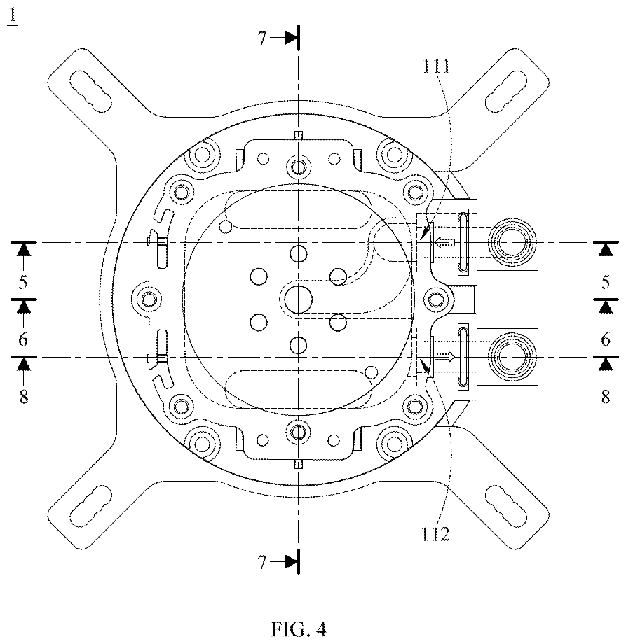

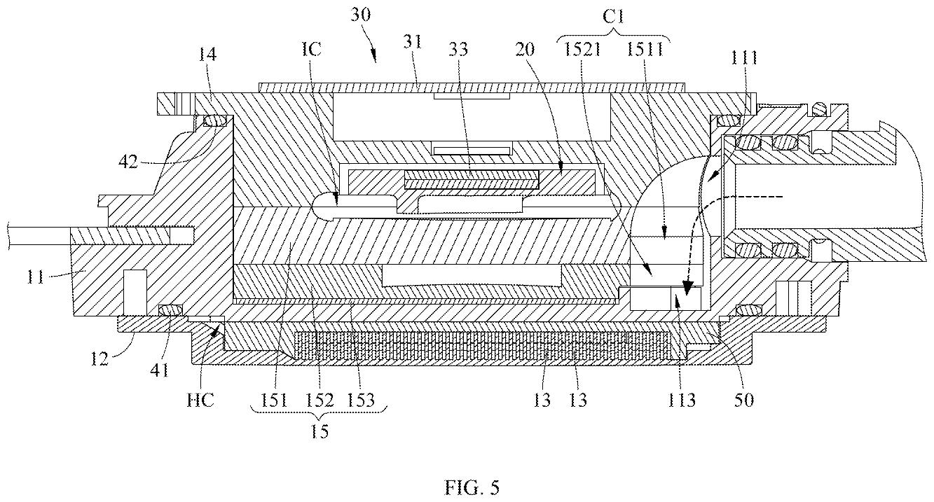

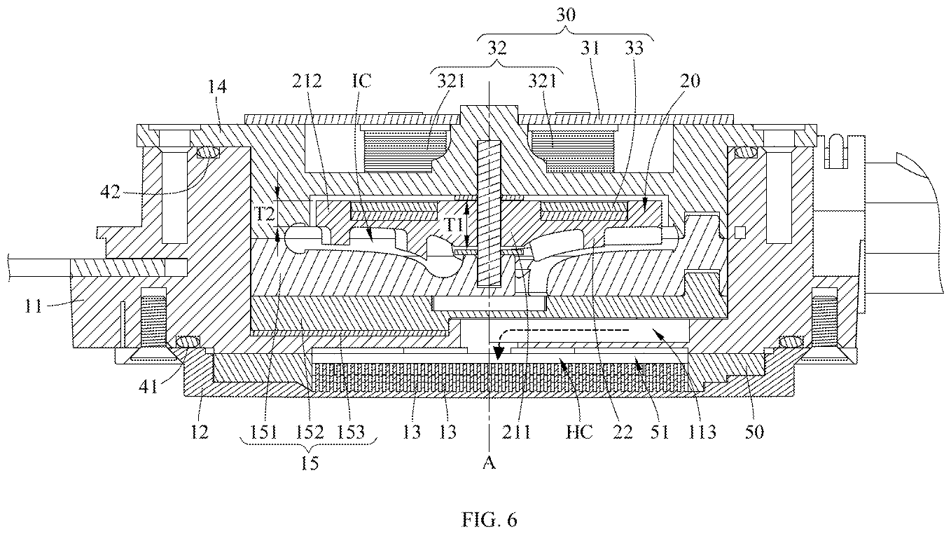

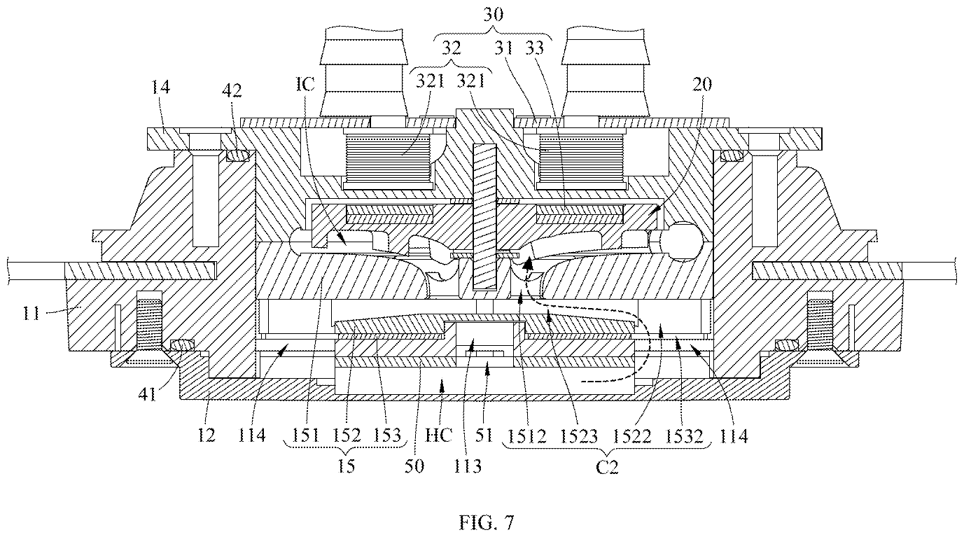

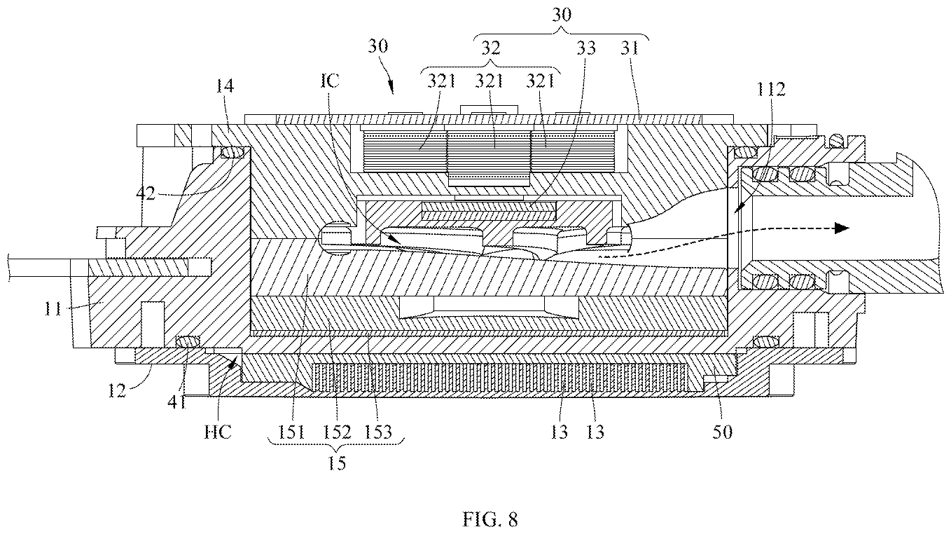

Next, please refer to FIGS. 2 and 4 to 8. FIG. 4 is a bottom view of the water-cooling head of FIG. 1. FIG. 5 is a cross-sectional view taken along section line 5-5 of FIG. 4. FIG. 6 is a cross-sectional view taken along section line 6-6 of FIG. 4. FIG. 7 is a cross-sectional view taken along section line 7-7 of FIG. 4. FIG. 8 is a cross-sectional view taken along section line 8-8 of FIG. 4.

The heat conducting member 12 and the cover 14 are respectively assembled on opposite sides of the base 11, and the heat conducting member 12 is configured to be thermally coupled to a heat source (not shown). The sealing member 41 is disposed between the heat conducting member 12 and the base 11, and the sealing member 42 is disposed between the cover 14 and the base 11. The heat conducting member 12 and the base 11 together form a heat exchange chamber HC. The fin structures 13 are located in the heat exchange chamber HC and are thermally coupled to the heat conducting member 12, so that heat generated by the heat source can be conducted to the fin structures 13 through the heat conducting member 12. The flow guide assembly 15 is disposed in the base 11. The flow guide assembly 15 and the cover 14 together form an impeller chamber IC. The base 11 has a liquid inlet 111 and a liquid outlet 112. The flow guide assembly 15 has a first communication passage C1 and a second communication passage C2. The first communication passage C1 communicates the liquid inlet 111 and the heat exchange chamber HC, and the second communication passage C2 communicates the heat exchange chamber HC and the impeller chamber IC.

For example, the flow guide assembly 15 includes a first water guide plate 151, a second water guide plate 152, and a third water guide plate 153 sequentially stacked. The first water guide plate 151 is closer to the impeller chamber IC than either the second water guide plate 152 or the third water guide plate 153. The first water guide plate 151 has a first opening 1511 and a second opening 1512. The first opening 1511 is located at a corner of the first water guide plate 151, and the second opening 1512 is located at a center of the first water guide plate 151. The second water guide plate 152 has a third opening 1521, two fourth openings 1522, and a groove 1523. The third opening 1521 is located at a corner of the second water guide plate 152. The two fourth openings 1522 are respectively located on opposite sides of the second water guide plate 152. The groove 1523 connects the two fourth openings 1522. The third water guide plate 153 has two fifth openings 1532. The two fifth openings 1532 are respectively located on opposite sides of the third water guide plate 153. The first opening 1511 and the third opening 1521 are aligned with each other, and the first opening 1511 and the third opening 1521 form the first communication passage C1. The second opening 1512 is aligned with the groove 1523. The two fourth openings 1522 are respectively aligned with the two fifth openings 1532. The second opening 1512, the groove 1523, the two fourth openings 1522, and the two fifth openings 1532 together form the second communication passage C2.

In this embodiment, the base 11 has a chamber inlet 113 and two chamber outlets 114. The two chamber outlets 114 are respectively located on opposite sides of the chamber inlet 113. Additionally, the water-cooling head 1 may further include a baffle plate 50. The baffle plate 50 is disposed in the heat exchange chamber HC between the base 11 and the heat conducting member 12. The baffle plate 50 has a slit 51. The chamber inlet 113 communicates with the heat exchange chamber HC through the slit 51. The first communication passage C1 communicates with the heat exchange chamber HC through the chamber inlet 113 and the slit 51. The second communication passage C2 communicates with the heat exchange chamber HC through the two chamber outlets 114.

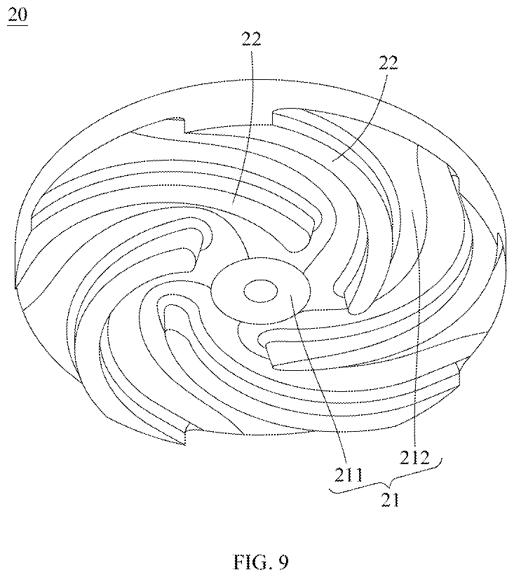

Please also refer to FIGS. 3, 6, and 9. FIG. 9 is a perspective view of the impeller of FIG. 2. The impeller 20 is disposed in the impeller chamber IC. The impeller 20 includes a disk portion 21 and a plurality of blades 22. The disk portion 21 includes a central portion 211 and a peripheral portion 212 surrounding the central portion 211. The maximum thickness T1 of the central portion 211 is greater than the thickness T2 of the peripheral portion 212. That is, the central portion 211 protrudes relative to the peripheral portion 212. The blades 22 are disposed on the peripheral portion 212.

As shown in FIGS. 2, 3, and 6, the motor 30 includes a circuit board 31, a stator assembly 32, and a rotor 33. The circuit board 31 is disposed on the cover 14 of the housing 10. The stator assembly 32 is disposed on the circuit board 31. The stator assembly 32 includes a plurality of coils 321. The rotor 33 is a magnet. The rotor 33 is disposed on the impeller 20. The stator assembly 32 and the rotor 33 are arranged along a rotation axis A of the impeller 20. When the stator assembly 32 is energized, a magnetic field is generated between the rotor 33 and the stator assembly 32 to drive the impeller 20 to rotate.

Next, the process of coolant flowing through the water-cooling head 1 will be described with reference to FIGS. 5 to 8. In FIGS. 5 to 8, dashed arrows represent the direction of coolant flow. Coolant entering the water-cooling head 1 from the liquid inlet 111 flows to the heat exchange chamber HC via the first communication passage C1 to exchange heat with the fin structures 13. Then, the coolant flows to the impeller chamber IC via the second communication passage C2, and then exits the water-cooling head 1 via the liquid outlet 112 while driven by the impeller 20.

In this embodiment, the housing 10 has the liquid inlet 111, the heat exchange chamber HC, the impeller chamber IC, and the liquid outlet 112 sequentially connected in communication. The impeller 20 is disposed in the impeller chamber IC. The circuit board 31 of the motor 30 is disposed on the housing 10, the stator assembly 32 is disposed on the circuit board 31, and the rotor 33 is disposed on the impeller 20. Coolant entering the water-cooling head 1 from the liquid inlet 111 first enters the heat exchange chamber HC to absorb heat. The coolant then enters the impeller chamber IC and exits the water-cooling head 1 from the liquid outlet 112 while driven by the impeller 20. This structural configuration can improve the heat exchange efficiency between the coolant and the water-cooling head 1, thereby improving the heat dissipation efficiency.

Additionally, the impeller 20 has a disk portion 21 with a central portion 211 and a peripheral portion 212. The maximum thickness T1 of the central portion 211 is greater than the thickness T2 of the peripheral portion 212. That is, the central portion 211 protrudes relative to the peripheral portion 212. The blades 22 are disposed on the peripheral portion 212. This structural design enhances the performance of the water-cooling head 1 and thereby improves its heat dissipation efficiency.

Compared with conventional water-cooling heads having the liquid inlet, impeller chamber, heat exchange chamber, and liquid outlet sequentially connected in communication, the water-cooling head 1 of this embodiment provides significant performance improvements. The flow rate increases from 71 liters per hour (L/H) to 100 liters per hour. The head increases from 155 cm/H₂O to 300 cm/H₂O. The rotational speed increases from 3400 rpm to 4500 rpm. Additionally, the temperature of the heat source is reduced by approximately 4.2° C.

In some embodiments, the number of fourth openings 1522 of the second water guide plate 152, the number of fifth openings 1532 of the third water guide plate 153, and the number of chamber outlets 114 of the base 11 are not limited to two, and may be modified to one in other embodiments.

Furthermore, the positions of the first opening 1511 and the second opening 1512 of the first water guide plate 151, the third opening 1521 and the fourth openings 1522 of the second water guide plate 152, and the fifth openings 1532 of the third water guide plate 153 are not intended to limit the present invention, and can be adjusted according to the specific needs of the application. Similarly, the flow guide assembly 15 may include more or fewer water guide plates than the three-plate configuration shown. The specific structure and configuration of the flow guide assembly 15 may be adapted based on the desired flow characteristics and heat exchange requirements.

In some embodiments, the chamber inlet 113 and chamber outlets 114 of the base 11 may be omitted or replaced with alternative flow channel configurations. The baffle plate 50 and sealing members 41, 42 are optional components that may be omitted or substituted with alternative sealing or flow-directing structures in various embodiments.

The housing 10 described above represents one possible configuration. Alternative housing configurations having different structural arrangements may be employed while preserving the functional linkages between the liquid inlet, heat exchange chamber, impeller chamber, and liquid outlet.

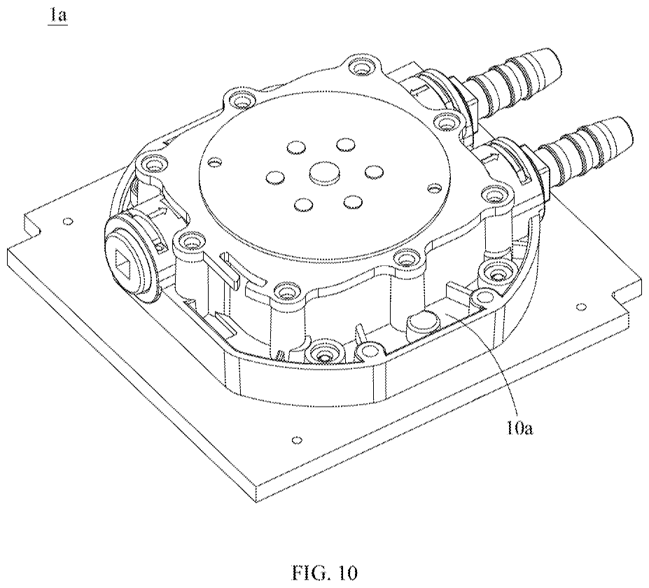

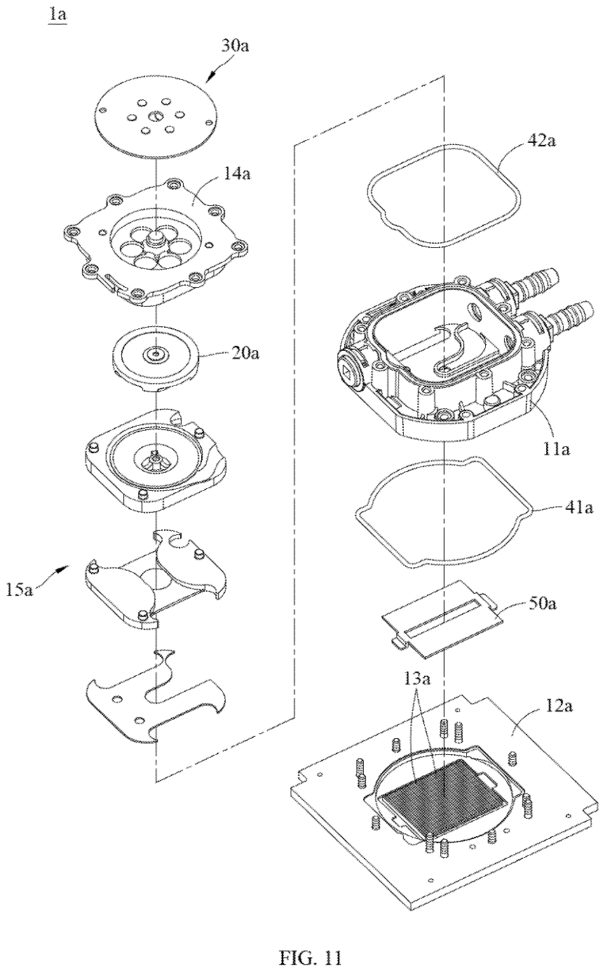

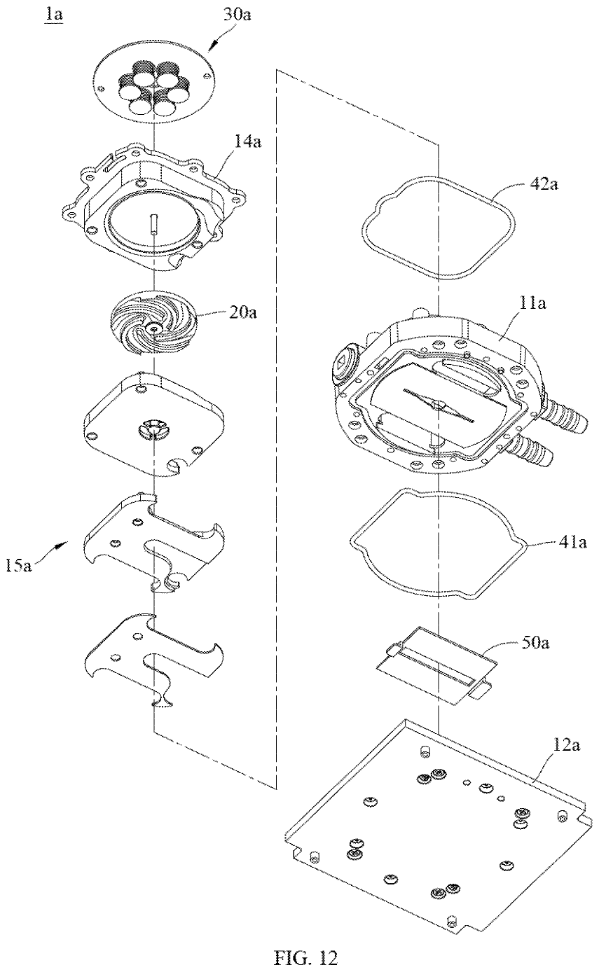

Next, please refer to FIGS. 10 to 12. FIG. 10 is a perspective view of a water-cooling head according to a second embodiment of the present disclosure. FIG. 11 is an exploded view of the water-cooling head of FIG. 10. FIG. 12 is an exploded view of the water-cooling head of FIG. 10 from another viewing angle.

The water-cooling head 1a of this embodiment is structurally and functionally similar to the water-cooling head 1 of the first embodiment. The water-cooling head 1a includes a housing 10a, an impeller 20a, a motor 30a, two sealing members 41a, 42a, and a baffle plate 50a. The housing 10a includes a base 11a, a heat conducting member 12a, a plurality of fin structures 13a, a cover 14a, and a flow guide assembly 15a. While the components 11a-15a, 20a, 30a, 41a, 42a, and 50a may have different external contours, profiles, or form factors compared to their counterparts in the first embodiment, the structural linkages and functional characteristics remain unchanged. Specifically, the liquid inlet, heat exchange chamber, impeller chamber, and liquid outlet remain sequentially connected in communication, the impeller 20a remains disposed in the impeller chamber, and the motor 30a preserves the same configuration with its circuit board on the cover 14a, stator assembly on the circuit board, and rotor on the impeller 20a. The coolant flow path and heat exchange operation are identical to those described in the first embodiment.

The foregoing embodiments provide a water-cooling head with improved heat dissipation efficiency. The sequential communication arrangement of the liquid inlet, heat exchange chamber, impeller chamber, and liquid outlet allows coolant to first absorb heat in the heat exchange chamber before being driven through the impeller chamber and out through the liquid outlet. By positioning the motor's circuit board on the housing, mounting the stator assembly on the circuit board, and coupling the rotor to the impeller within the impeller chamber, the disclosed configuration achieves enhanced heat exchange efficiency between the coolant and the water-cooling head structure.

Although the present disclosure has been disclosed with the above preferred embodiments, they are not intended to limit the present disclosure. Those skilled in the art can make some modifications and refinements without departing from the spirit and scope of the present disclosure. Therefore, the scope of patent protection of the present disclosure shall be defined by the scope of the claims attached to this specification.

What is claimed is:

1. A water-cooling head comprising:
a housing having a liquid inlet, a heat exchange chamber, an impeller chamber, and a liquid outlet sequentially connected with each other;
an impeller disposed in the impeller chamber; and
a motor including a circuit board, a stator assembly, and a rotor, wherein the circuit board is disposed on the housing, the stator assembly is disposed on the circuit board, and the rotor is disposed on the impeller.

2. The water-cooling head of claim 1, wherein the housing comprises a base, a heat conducting member, a cover, and a flow guide assembly, the liquid inlet and the liquid outlet are located on the base, the heat conducting member and the cover are respectively assembled on opposite sides of the base, the heat conducting member and the base together form the heat exchange chamber, the circuit board is disposed on the cover, the flow guide assembly is disposed in the base, the flow guide assembly and the cover together form the impeller chamber, the flow guide assembly has a first communication passage and a second communication passage, the first communication passage communicates the liquid inlet and the heat exchange chamber, and the second communication passage communicates the heat exchange chamber and the impeller chamber.

3. The water-cooling head of claim 2, wherein the flow guide assembly comprises a first water guide plate, a second water guide plate, and a third water guide plate sequentially stacked, the first water guide plate is closer to the impeller chamber than either the second water guide plate or the third water guide plate, the first water guide plate has a first opening and a second opening, the second water guide plate has a third opening and at least one fourth opening, the third water guide plate has at least one fifth opening, the first opening and the third opening together form the first communication passage, and the second opening, the at least one fourth opening, and the at least one fifth opening together form the second communication passage.

4. The water-cooling head of claim 3, wherein the first opening is located at a corner of the first water guide plate, the second opening is disposed at a center of the first water guide plate, the third opening is disposed at a corner of the second water guide plate, the at least one fourth opening is disposed on a side of the second water guide plate, the second water guide plate further has a groove, the groove connects the at least one fourth opening, the at least one fifth opening is disposed on a side of the third water guide plate, the first opening and the third opening are aligned with each other, the second opening is aligned with the groove, the at least one fourth opening is aligned with the at least one fifth opening, and the second opening, the groove, the at least one fourth opening, and the at least one fifth opening together form the second communication passage.

5. The water-cooling head of claim 4, wherein the number of the at least one fourth opening is two, the two fourth openings are respectively disposed on opposite sides of the second water guide plate, the number of the at least one fifth opening is two, the two fifth openings are respectively disposed on opposite sides of the third water guide plate, and the two fourth openings are respectively aligned with the two fifth openings.

6. The water-cooling head of claim 2, wherein the base includes a chamber inlet and at least one chamber outlet, the at least one chamber outlet is disposed on a side of the chamber inlet, the first communication passage communicates with the heat exchange chamber through the chamber inlet, and the second communication passage communicates with the heat exchange chamber through the at least one chamber outlet.

7. The water-cooling head of claim 6, further comprising a baffle plate disposed between the base and the heat conducting member, wherein the baffle plate has a slit, and the chamber inlet communicates with the heat exchange chamber through the slit.

8. The water-cooling head of claim 2, further comprising two sealing members, wherein one of the two sealing members is disposed between the heat conducting member and the base, and the other of the two sealing members is disposed between the cover and the base.

9. The water-cooling head of claim 1, wherein the impeller comprises a disk portion and a plurality of blades, the disk portion comprises a central portion and a peripheral portion surrounding the central portion, a maximum thickness of the central portion is greater than a thickness of the peripheral portion, and the blades are disposed on the peripheral portion.

10. The water-cooling head of claim 1, wherein the stator assembly and the rotor are arranged along a rotation axis of the impeller.
